(19) United States
(12) Patent Application Publication
(10) Pub. No.: US 2025/0309057 A1
(43) Pub. Date: Oct. 2, 2025

(54) SEMICONDUCTOR DEVICE AND METHOD FOR MANUFACTURING THE SAME

(71) Applicant: Samsung Electronics Co., Ltd., Suwon-si (KR)

(72) Inventors: Je Gwan Hwang, Suwon-si (KR); Ji Hyung Kim, Suwon-si (KR)

(21) Appl. No.: 18/937,184

(22) Filed: Nov. 5, 2024

(30) Foreign Application Priority Data
Mar. 27, 2024 (KR) 10-2024-0041561

(51) Int. Cl. H01L 23/48; H01L 29/06

(52) U.S. Cl. CPC H01L 23/481; H10D 62/102

(57) ABSTRACT

A semiconductor device includes a substrate, a first impurity area in the substrate, a via structure extending in a first direction and into the first impurity area, a second impurity area that surrounds at least a portion of the via structure, a first contact that is on the second impurity area and electrically connected to the second impurity area, a first wiring layer that is on the first contact and electrically connected to the first contact, and a second wiring layer that is on the first wiring layer and electrically connected to a ground.

### CROSS-REFERENCE TO RELATED APPLICATIONS

This application claims priority from Korean Patent Application No. 10-2024-0041561 filed on Mar. 27, 2024 in the Korean Intellectual Property Office, and all the benefits accruing therefrom under 35 U.S.C. 119, the contents of which in its entirety are herein incorporated by reference.

### TECHNICAL FIELD

The present disclosure relates to a semiconductor device and a method for manufacturing the same. More specifically, the present disclosure relates to a semiconductor device including a TSV (Through Silicon Via) and a method for manufacturing the same.

### BACKGROUND OF THE INVENTION

As the development of a 3-dimensional (3D) package in which a plurality of semiconductor integrated circuit elements are mounted in a semiconductor package becomes more active, a through silicon via (TSV) which extends through a substrate or a die for vertical electrical connection formation may be included as part of the 3D package.

The TSV may function, for example, as a signal line and/or a power supply line for the semiconductor device. In this case, the TSV may generate electrical noise that adversely affects the semiconductor device. In order to improve performance and reliability of the 3D package, there is a need to form a TSV that may reduce such noise.

### SUMMARY OF THE INVENTION

A technical purpose that the present disclosure seeks to achieve is to provide a semiconductor device with improved reliability.

Another technical purpose that the present disclosure seeks to achieve is to provide a method for manufacturing a semiconductor device with improved reliability.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims and combinations thereof.

A semiconductor device according to some embodiments of the present disclosure for achieving the above technical purpose includes a substrate, a first impurity area in the substrate, a via structure extending in a first direction and into the first impurity area, a second impurity area that surrounds at least a portion of the via structure, a first contact that is on the second impurity area and electrically connected to the second impurity area, a first wiring layer that is on the first contact and electrically connected to the first contact, and a second wiring layer that is on the first wiring layer and electrically connected to a ground.

A semiconductor device according to some embodiments of the present disclosure for achieving the above technical purpose includes a substrate that includes a first surface extending in a first direction and a second direction that intersect each other, an impurity area that is in the substrate and includes a first area and a second area, a via structure including: a via hole that extends into the first area and in a third direction that is perpendicular to the first direction and the second direction; and a conductive via in the via hole, a first contact on the second area, a first wiring layer electrically connected to the impurity area, and a second wiring layer electrically connected to a ground, where in a plan view, the impurity area, the first contact, and the first wiring layer surround at least a portion of a sidewall of the via structure.

A semiconductor device according to some embodiments of the present disclosure for achieving the above technical purpose includes a substrate including a first area and a second area, a via structure that extends in a first direction and into the first area of the substrate, a first impurity area that is in the first area of the substrate and contacts the via structure, a first wiring structure electrically connected to the first impurity area, where the first wiring structure includes: a first contact on the first area of the substrate; and a first wiring layer that is on the first contact and electrically connected to the first contact, a second impurity area in the second area of the substrate, a gate structure on the second area of the substrate, and a second wiring structure electrically connected to the second impurity area, where the second wiring structure includes: a second contact on the second area of the substrate; and a second wiring layer that is on the second contact and electrically connected to the second contact, where a distance between an upper surface of the first contact and an upper surface of the substrate in the first direction is equal to a distance between an upper surface of the second contact and the upper surface of the substrate in the first direction.

Specific details of other embodiments are included in the description and drawings of the present disclosure.

### BRIEF DESCRIPTION OF DRAWINGS

The above and other aspects and features of the present disclosure will become more apparent by describing in detail exemplary embodiments thereof with reference to the attached drawings, in which:

FIG. 1 is a plan view for illustrating a semiconductor device according to some embodiments;

FIG. 2 is a cross-sectional view taken along a line I-I′ in FIG. 1;

FIG. 3 is a cross-sectional view taken along a line II-II′ in FIG. 1;

FIG. 4 is a diagram for illustrating a semiconductor device according to some embodiments, and is a diagram corresponding to FIG. 2;

FIG. 5 is a diagram for illustrating a semiconductor device according to some embodiments, and is a diagram corresponding to FIG. 2;

FIG. 6 is a diagram for illustrating a semiconductor device according to some embodiments, and is a diagram corresponding to FIG. 2;

FIG. 7 is a plan view for illustrating a semiconductor device according to some embodiments;

FIG. 8 and FIG. 9 are diagrams schematically showing a semiconductor package to which a semiconductor device according to some embodiments may be applied;

FIGS. 10, 11, 12, 13, 14, 15, 16, 17, 18, and 19 are diagrams of intermediate structures corresponding to intermediate steps of a method for manufacturing a semiconductor device according to some embodiments.

### DETAILED DESCRIPTIONS

To clarify the present disclosure, the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction.

Hereinafter, embodiments of the present disclosure are described in detail with reference to the attached drawings. The same reference numerals are used for the same components in the drawings, and duplicate descriptions thereof are omitted herein.

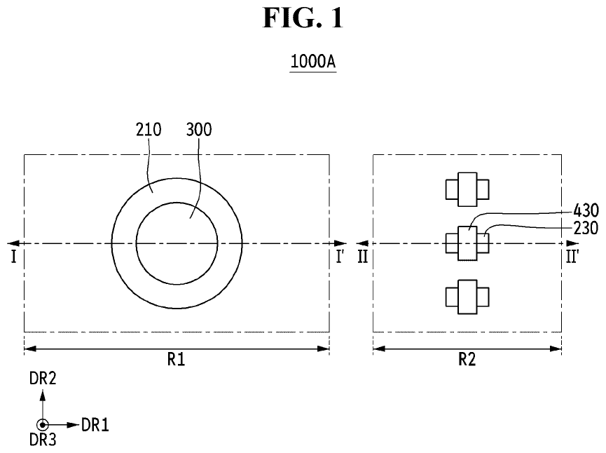

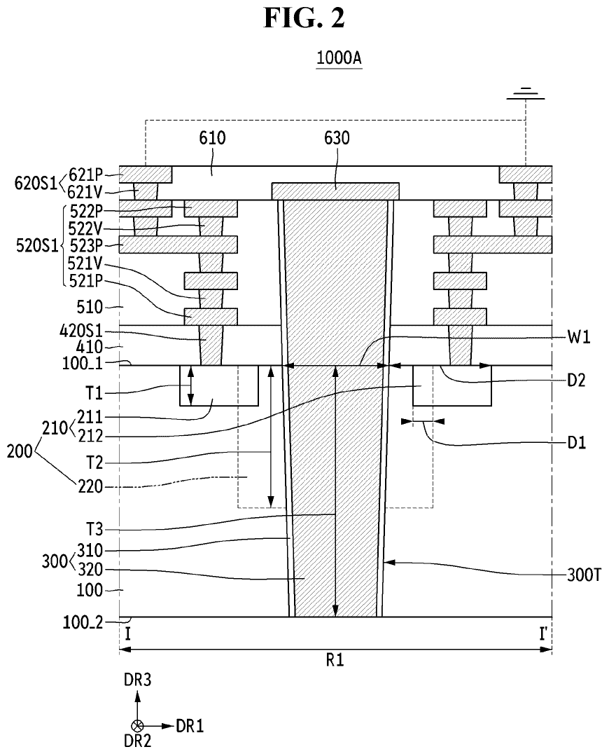

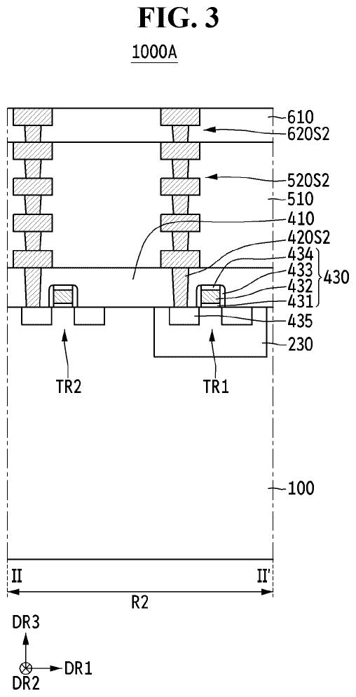

FIG. 1 is a plan view for illustrating a semiconductor device according to some embodiments. FIG. 2 is a cross-sectional view taken along a line I-I′ in FIG. 1. FIG. 3 is a cross-sectional view taken along a line II-II′ in FIG. 1.

Referring to FIGS. 1 to 3, a semiconductor device 1000A according to some embodiments may include a substrate 100, a first impurity area 200, a via structure 300, a first contact 420S1, a first wiring layer 520S1, and a second wiring layer 620S1, and may further include a second impurity area 230, a gate structure 430, a second contact 420S2, a third wiring layer 520S2, and a fourth wiring layer 620S2.

The substrate 100 may include a first area R1 and a second area R2. The first area R1 may be an area where a via hole 300T, which will be described later, is formed, and the second area R2 may be an area where semiconductor elements, for example, transistors TR1 and TR2 are formed.

The substrate 100 may include a first surface 100_1 and a second surface 100_2 that are opposite to each other. The first surface 100_1 may extend in each of first and second directions DR1 and DR2 that intersect each other. The first and second directions DR1 and DR2 may be parallel to the first surface 100_1, and a third direction DR3 may be perpendicular to each of the first and second directions DR1 and DR2.

The substrate 100 may include a semiconductor material or an insulating material. In some embodiments, the substrate 100 may include, for example, silicon, germanium, silicon-germanium, gallium-arsenide (GaAs), glass, ceramic, etc.

The first impurity area 200 may be formed within the substrate 100 of the first area R1. The first impurity area 200 may include first and second impurity areas 210 and 220. The first and second impurity areas 210 and 220 may be disposed to surround at least a portion of the via structure 300. In a plan view, a shape of the first impurity area 210 may be circular. Furthermore, in the plan view, a shape of the second impurity area 220 may be circular.

The first impurity area 210 may include impurity areas 211 and 212 spaced apart from each other in the first direction DR1.

That is, in the plan view, the first impurity area 210 may surround the via structure 300, while in a cross-sectional view, the first impurity area 210 may include the impurity areas 211 and 212 disposed around the via structure 300.

A depth in the third direction DR3 of the second impurity area 220 may be different from a depth in the third direction DR3 of the first impurity area 210. A width in the first direction DR1 and/or the second direction DR2 of the second impurity area 220 may be different from a width in the first direction DR1 and/or the second direction DR2 of the first impurity area 210. However, the technical idea of the present disclosure is not limited thereto.

For example, a depth T2 in the third direction DR3 of the second impurity area 220 from the first surface 100_1 of the substrate 100 may be greater than a depth T1 in the third direction DR3 of the first impurity area 210 from the first surface 100_1 of the substrate 100. However, the technical idea of the present disclosure is not limited thereto.

In a plan view, at least a portion of the first impurity area 210 may overlap with at least a portion of the second impurity area 220 in the first direction DR1 and/or the third direction DR3. For example, each of the first and second impurity areas 210 and 220 may at least partially overlap with each other by a first distance D1 in the first direction DR1. However, the technical idea of the present disclosure is not limited thereto.

The first and second impurity areas 210 and 220 may be electrically connected to each other. The first and second impurity areas 210 and 220 may include the same conductive type material. For example, when the first impurity area 210 is of an N-type conductivity, the second impurity area 220 may be of an N-type conductivity. When the first impurity area 210 is of a P-type conductivity, the second impurity area 220 may be of a P-type conductivity.

The via structure 300 may extend into the second impurity area 220 in the third direction DR3. The via structure 300 may be connected to the first impurity area 200.

The via structure 300 may include a via hole 300T extending in the third direction DR3 and into the substrate 100, an insulating film 310 conformally extending on and along an inner sidewall of the via hole 300T, and a conductive via 320 that fills or is in the via hole 300T.

The via hole 300T may extend through the substrate 100 in the third direction DR3 from the first surface 100_1 to the second surface 100_2. For example, a depth T3 of the via hole 300T formed in the third direction DR3 from the first surface 100_1 of the substrate 100 may be in a range of 0.5 to 46 μm. However, embodiments of the present disclosure are not limited thereto.

In a plan view, a shape of the via hole 300T may have various shapes, such as circular or polygonal shapes. For example, based on the first surface 100_1 of the substrate 100, a width W1 in the first direction DR1 of the via hole 300T may be 80 to 4000 nm. However, embodiments of the present disclosure are not limited thereto.

The insulating film 310 may be formed to prevent or inhibit interference between the conductive via 320 and the substrate 100. For example, the insulating film 310 may include an insulating material such as an oxide.

The conductive via 320 may include a conductive material. Although not specifically shown, the conductive via 320 may include a seed layer and a conductive layer on the insulating film 310. The seed layer may be conformally formed on a sidewall of the insulating film 310 and may serve as a seed for the conductive layer. The conductive layer may fill or be in the remaining portion of the via hole 300T using the seed layer. Electrical signals and/or power may be supplied through the conductive via 320.

In a plan view, the first and second impurity areas 210 and 220 may surround at least a portion of a sidewall of the via structure 300. In the plan view, the first impurity area 210 may surround at least a portion of the second impurity area 220.

The second impurity area 220 may be interposed between the first impurity area 210 and the via structure 300. The second impurity area 220 and at least a portion of the sidewall of the via structure 300 may contact each other. The first impurity area 210 and at least a portion of the sidewall of the via structure 300 may not contact each other.

The first contact 420S1 may be disposed within the first interlayer insulating film 410. The first contact 420S1 may be disposed on the first impurity area 210 and electrically connected to the first impurity area 210. The first contact 420S1 may extend into the first interlayer insulating film 410 in the third direction DR3 so as to be connected to the first impurity area 210. The first contact 420S1 may be formed in a middle-of-line (MOL) formation process.

The first wiring layer 520S1 may be disposed within the second interlayer insulating film 510. The first wiring layer 520S1 may be disposed on the first contact 420S1 and the first interlayer insulating film 410. The first wiring layer 520S1 may be electrically connected to the first impurity area 210 and the first contact 420S1. The first wiring layer 520S1 may be formed in a back-end-of-line (BEOL) forming process.

The first wiring layer 520S1 may include a plurality of wiring structures for electrically connecting individual elements formed in the substrate 100 to each other or connecting the semiconductor device 1000A with another semiconductor device.

The second wiring layer 620S1 may be formed within the third interlayer insulating film 610. The second wiring layer 620S1 may be disposed on the first wiring layer 520S1 and may be electrically connected to the first impurity area 210, the first contact 420S1, and the first wiring layer 520S1.

In a plan view, the first contact 420S1, the first wiring layer 520S1, and the second wiring layer 620S1 may surround at least a portion of the sidewall of the via structure 300. In the plan view, each of the first contact 420S1, the first wiring layer 520S1, and the second wiring layer 620S1 may have various shapes, such as a circular or polygonal shape.

The first wiring layer 520S1 may be disposed outwardly of the via structure 300. For example, a distance D2 between an area where the first wiring layer 520S1 is disposed in the first direction DR1 and the sidewall of the via structure 300 may be in a range of 0.25 to 3 μm. However, embodiments of the present disclosure are not limited thereto.

The second wiring layer 620S1 may be disposed outwardly of the first wiring layer 520S1. That is, the first wiring layer 520S1 except a connection pad 523P may not overlap the second wiring layer 620S1 (e.g., are free from overlap) in the third direction DR3.

In this case, a distance in the first direction DR1 between an area where the second wiring layer 620S1 is disposed and the sidewall of the via structure 300 may be different from the distance D2 between the area where the first wiring layer 520S1 is disposed in the first direction DR1 and the sidewall of the via structure 300.

For example, the distance in the first direction DR1 between an area where the second wiring layer 620S1 is disposed and the sidewall of the via structure 300 may be larger than the distance D2 between the area where the first wiring layer 520S1 is disposed in the first direction DR1 and the sidewall of the via structure 300. However, the technical idea of the present disclosure is not limited thereto.

The first wiring layer 520S1 may include a plurality of pads 521P and 522P and vias 521V and 522V that are electrically connected to the first impurity area 200 and the first contact 420S1. The vias 521V and 522V may electrically connect the pads 521P and 522P to each other while being disposed therebetween.

The second wiring layer 620S1 may include a pad 621P and a via 621V that are electrically connected to a ground. The via 621V may be electrically connected to the pad 621P.

The first wiring layer 520S1 may further include a connection pad 523P to be electrically connected to the second wiring layer 620S1. The connection pad 523P may be disposed between the uppermost pad 522P and the lowermost pad 521P of the first wiring layer 520S1.

The number of pads and vias, and the number of layers thereof included in each of the first wiring layer 520S1 and the second wiring layer 620S1 are not limited to those as shown.

Each of the first contact 420S1, the first wiring layer 520S1, and the second wiring layer 620S1 may include, for example, a conductive material. For example, each of the first contact 420S1, the first wiring layer 520S1, and the second wiring layer 620S1 may include at least one metal selected from copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn) and carbon (C) or a metal alloy thereof.

A via pad 630 may be disposed on the via structure 300. The via pad 630 may be formed in the third interlayer insulating film 610 and may be electrically connected to the via structure 300.

The via pad 630 may include, for example, a conductive material. For example, the via pad 630 may include at least one metal selected from copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn) and carbon (C) or a metal alloy thereof.

The second impurity area 230 may be formed within the substrate 100 and in the second area R2. The second impurity area 230 may be disposed to contact the first surface 100_1 of the substrate 100. The second impurity area 230 may be of the N-type conductivity or the P-type conductivity.

A gate structure 430 may be disposed on the second impurity area 230. The gate structure 430 may include a gate dielectric film 431, a gate electrode 432, and a capping film 434 stacked on the second impurity area 230. The gate dielectric film 431 may include an insulating material such as an oxide, and the gate electrode 432 may include a conductive material such as metal and/or polysilicon. A spacer 433 may be disposed on a sidewall of the gate electrode 432.

Source and drain areas 435 may be formed in the second impurity area 230 and may be respectively on both opposing sides of the gate electrode 432. The source and drain areas 435 may be formed to be spaced apart from each other and within the second impurity area 230 and may be disposed to contact the first surface 100_1 of the substrate 100. For example, when the second impurity area 230 is of the N-type conductivity, the source and drain areas 435 may be of the P-type conductivity. When the second impurity area 230 is of the P-type conductivity, the source/drain areas 435 may be of the N-type conductivity.

A plurality of second impurity areas 230 may be present. Thus, a plurality of gate structures 430 may be respectively disposed on the second impurity areas 230. For example, as shown in FIG. 1, the plurality of gate structures 430 may be respectively disposed on the plurality of second impurity areas 230. FIG. 1 shows three second impurity areas 230 and three gate structures 430 by way of example. However, the number of second impurity areas 230 and the number of gate structures 430 present in the second area R2 may vary.

The first impurity area 200 and the second impurity area 230 may be spaced apart from each other in the first direction DR1 and electrically insulated or separated from each other. Accordingly, the via hole 300T and the second impurity area 230 may be spaced apart from each other in the first direction DR1 and electrically separated from each other. The first impurity area 200 and the second impurity area 230 may be formed at the same time. The first impurity area 200 may be of the N-type conductivity or P-type conductivity.

The second contact 420S2 may be disposed on the first surface 100_1 of the substrate 100 and may be electrically connected to the third impurity area 230. The first contact 420S1 and the second contact 420S2 may be located at the same vertical level in the third direction DR3 (e.g., the distances between the first surface 100_1 of the substrate 100 and the upper surfaces of the first and second contacts 420S1, 420S2 in the third direction D3 is the same).

The third wiring layer 520S2 may be electrically connected to the second contact 420S2 while being disposed on the second contact 420S2. The first wiring layer 520S1 and the third wiring layer 520S2 may be located at the same vertical level in the third direction DR3 (e.g., the distances between the first surface 100_1 of the substrate 100 and the upper surfaces of the first and third wiring layers 520S1, 520S2 in the third direction D3 is the same).

The fourth wiring layer 620S2 may be electrically connected to the third wiring layer 520S2. The second wiring layer 620S1 and the fourth wiring layer 620S2 may be located at the same vertical level in the third direction DR3 (e.g., the distances between the first surface 100_1 of the substrate 100 and the upper surfaces of the second and fourth wiring layers 620S1, 620S2 in the third direction D3 is the same).

The number of pads and vias and the number of layers thereof included in each of the third wiring layer 520S2 and the fourth wiring layer 620S2 are not limited to those as shown.

For example, each of the second contact 420S2, the third wiring layer 520S2, and the fourth wiring layer 620S2 may include a conductive material. For example, each of the second contact 420S2, the third wiring layer 520S2, and the fourth wiring layer 620S2 may include at least one metal selected from copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn) and carbon (C) or a metal alloy thereof.

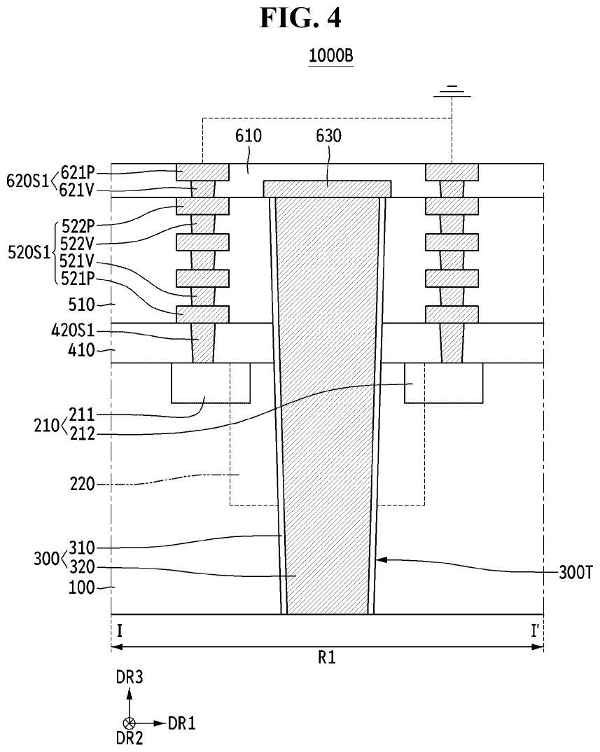

FIG. 4 is a diagram for illustrating a semiconductor device according to some embodiments, and is a diagram corresponding to FIG. 2. For convenience of description, differences thereof from the contents described above with reference to FIG. 1 to FIG. 3 will be mainly described.

Referring to FIG. 4, the second wiring layer 620S1 of a semiconductor device 1000B according to some embodiments may overlap at least a portion of the first wiring layer 520S1 in the third direction DR3.

For example, the distance in the first direction DR1 between an area where the second wiring layer 620S1 is disposed and the sidewall of the via structure 300 may be equal to the distance D2 between the area where the first wiring layer 520S1 is disposed in the first direction DR1 and the sidewall of the via structure 300.

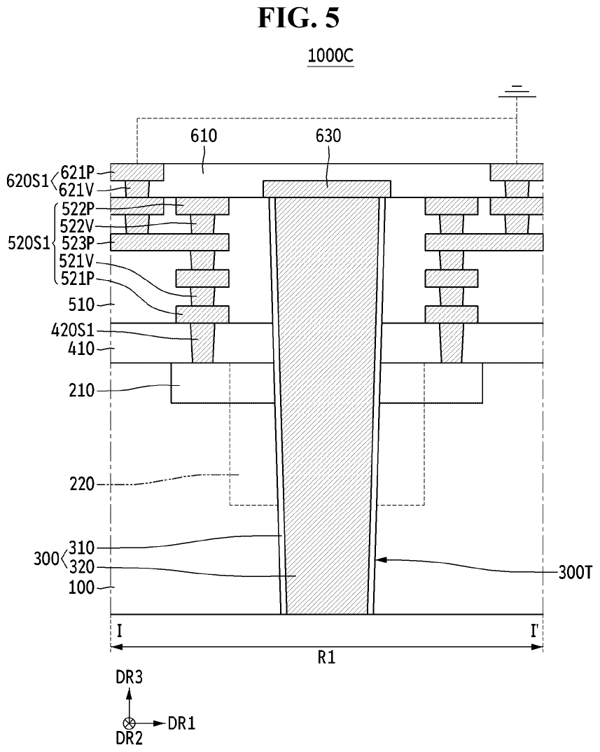

FIG. 5 is a diagram for illustrating a semiconductor device according to some embodiments, and is a diagram corresponding to FIG. 2. For convenience of description, differences thereof from the contents described above with reference to FIG. 1 to FIG. 4 will be mainly described.

Referring to FIG. 5, the first impurity area 210 of a semiconductor device 1000C according to some embodiments may be integrated into a single area in a cross-sectional view. In this case, at least a portion of the first impurity area 210 and the sidewall of the via structure 300 may directly contact each other.

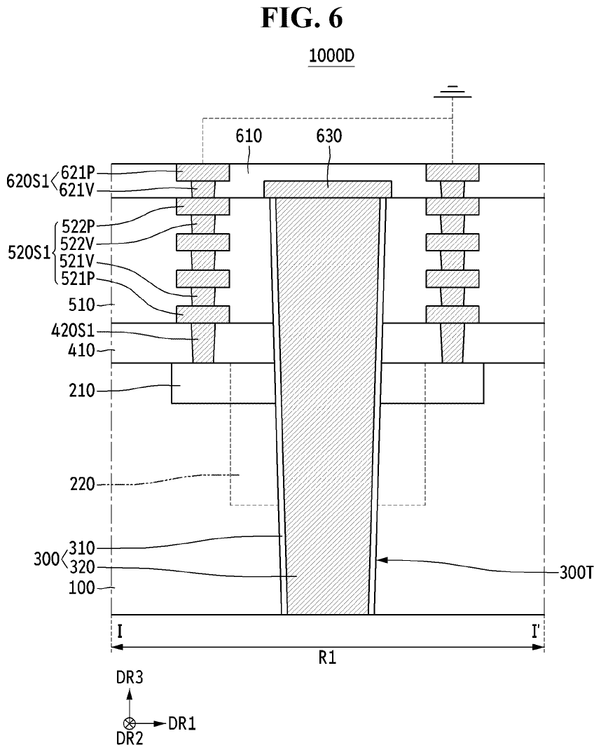

FIG. 6 is a diagram for illustrating a semiconductor device according to some embodiments, and is a diagram corresponding to FIG. 2.

For convenience of description, differences thereof from the contents described above with reference to FIG. 1 to FIG. 5 will be mainly described.

Referring to FIG. 6, the second wiring layer 620S1 of a semiconductor device 1000D according to some embodiments may overlap at least a portion of the first wiring layer 520S1 in the third direction DR3.

For example, based on the first direction DR1, the distance in the first direction DR1 between an area where the second wiring layer 620S1 is disposed and the sidewall of the via structure 300 may be equal to the distance D2 between the area where the first wiring layer 520S1 is disposed in the first direction DR1 and the sidewall of the via structure 300.

The first impurity area 210 may be integrated into a single area in a cross-sectional view. In this case, at least a portion of the first impurity area 210 and the sidewall of the via structure 300 may directly contact each other.

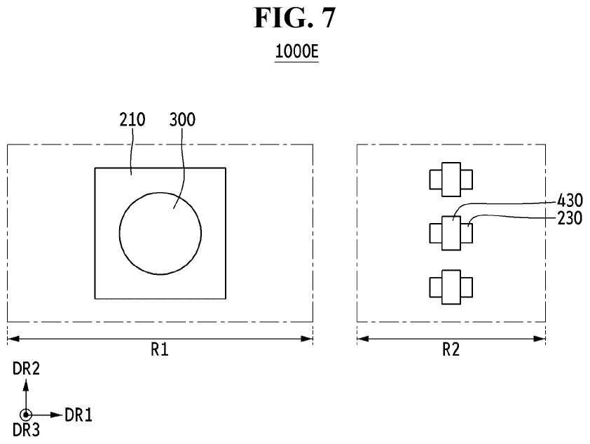

FIG. 7 is a plan view for illustrating a semiconductor device according to some embodiments. For convenience of description, differences thereof from the contents described above with reference to FIG. 1 to FIG. 6 will be mainly described.

Referring to FIG. 7, in a plan view of a semiconductor device 1000E according to some embodiments, a shape of the first impurity area 210 may be a square. Furthermore, in the plan view, a shape of the second impurity area 220 may be a square.

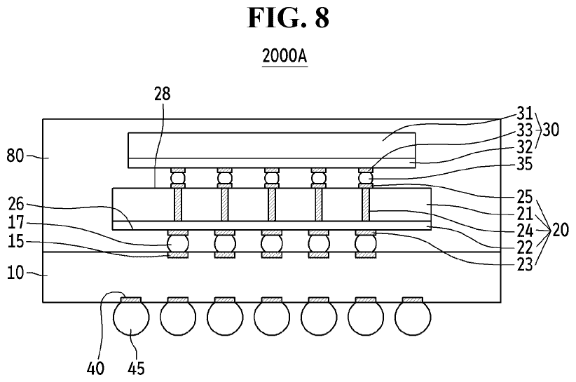

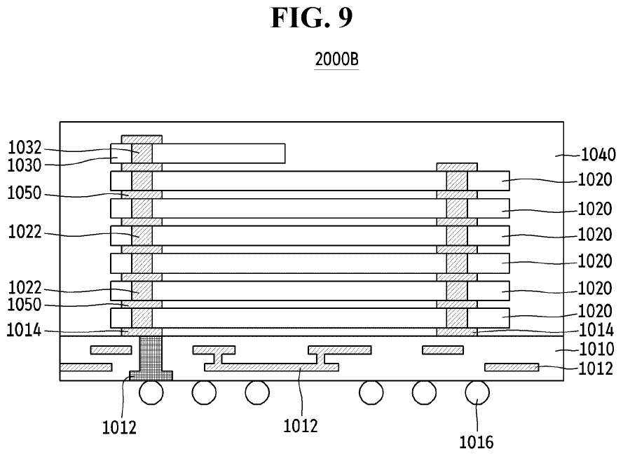

FIG. 8 and FIG. 9 are diagrams schematically showing a semiconductor package to which a semiconductor device according to some embodiments may be applied. For convenience of description, differences thereof from the contents described above with reference to FIG. 1 to FIG. 7 will be mainly described.

FIG. 8 is an example cross-sectional view of a semiconductor package 2000A including one or more of the semiconductor devices 1000A to 1000E according to some embodiments of the present disclosure.

Referring to FIG. 8, the semiconductor package 2000A may include a package substrate 10, a first semiconductor device 20, a second semiconductor device 30, and a molding layer 80.

The package substrate 10 may include a substrate, for example, made of glass, ceramic, or plastic, and a circuit in a predetermined shape formed thereon. However, embodiments of the present disclosure are not limited thereto.

An external terminal 45 may be formed on a lower surface of the package substrate 10 to electrically connect the semiconductor package 2000A to an external device (not shown). The external terminal 45 may be formed as a grid array such as a pin grid array, a ball grid array, or a land grid array.

A package lower pad 40 may be electrically connected to the external terminal 45 connected to the external device, and the package substrate 10 may supply an electrical signal to the first semiconductor device 20 and the second semiconductor device 30 via a package substrate upper pad 15 formed on an upper surface of the package substrate 10. At least one of the package lower pads 40 may be, for example, a ground pad and may be electrically connected to a ground line within the package substrate 10. In FIG. 8, the package lower pad 40 is shown as being disposed in a center of the package substrate 10. However, embodiments of the present disclosure are not limited thereto.

The first semiconductor device 20 and the second semiconductor device 30 may be sequentially stacked on the package substrate 10. Specifically, the first semiconductor device 20 may be disposed on the package substrate 10, and the second semiconductor device 30 may be disposed on the first semiconductor device 20. Each of the first semiconductor device 20 and the second semiconductor device 30 may be, for example, in a form of a flip chip. However, embodiments of the present disclosure are not limited thereto.

Each of the second semiconductor device 30 and the first semiconductor device 20 may be, for example, a memory chip, a logic chip, etc. When the second semiconductor device 30 and/or the first semiconductor device 20 is a logic chip, the second semiconductor device 30 and/or the first semiconductor device 20 may be designed based on various operations, etc. as performed thereby. In this regard, the logic chip may be a micro-processor, for example a central processing unit (CPU), a controller, or an application specific integrated circuit (ASIC), etc.

When the second semiconductor device 30 and/or the first semiconductor device 20 is a memory chip, the memory chip may be, for example, a volatile memory such as DRAM or SRAM, or a non-volatile memory such as a flash memory. Specifically, the memory chip may be a flash memory chip. More specifically, the memory chip may be either a NAND flash memory chip or a NOR flash memory chip. A form of the memory chip according to the technical idea of the present disclosure is not limited thereto. In some embodiments of the present disclosure, the memory chip may include one of phase-change random-access memory (PRAM), magneto-resistive random-access memory (MRAM), and resistive random-access memory (RRAM).

The first semiconductor device 20 may be at least one of the semiconductor devices 1000A to 1000E according to some embodiments of the present disclosure. Accordingly, the first semiconductor device 20 may include a substrate 21, a via structure 24 (e.g., the via structure 300), a BEOL structure 22, a second connection pad 25, and a first connection pad 23. A detailed description of the first semiconductor device 20 has been described in detail using FIGS. 1 to 7, and thus will be omitted. In FIG. 8, it is shown that the first and second impurity areas 200 and 230 and the gate structure 430 are omitted.

A second connection pad 25 disposed on the second surface 28 may be electrically connected to a connection pad 33 of the second semiconductor device 30, and the second connection pad 25 may be electrically connected to the via structure 24. Accordingly, the first semiconductor device 20 and the second semiconductor device 30 may be electrically connected to each other via the via structure 24.

In some embodiments, the first semiconductor device 20 is shown as a single chip. However, the present disclosure is not limited thereto.

The first semiconductor device 20 may be electrically connected to the package substrate 10 via a first connection pad 23 formed on the first surface 26. Specifically, a first bump 17 may be disposed between the first connection pad 23 and a package substrate upper pad 15 to electrically connect the first connection pad 23 and the package substrate upper pad 15 to each other.

The first semiconductor device 20 may be electrically connected to the second semiconductor device 30. The second connection pad 25 of the first semiconductor device 20 may be connected to the connection pad 33 of the second semiconductor device 30 via a second bump 35, such that the first semiconductor device 20 may be electrically connected to the second semiconductor device 30.

The second semiconductor device 30 may include a substrate 31 and a semiconductor integrated circuit 32 formed thereon. The connection pad 33 may be formed on the semiconductor integrated circuit 32 of the second semiconductor device 30.

The second semiconductor device 30 may be electrically connected to the package substrate 10 via the via structure 24 formed within the first semiconductor device 20. Specifically, the second semiconductor device 30 may be electrically connected to the package substrate 10 via the connection pad 33, the second connection pad 25, the via structure 24, the first connection pad 23, and the package substrate upper pad 15.

In some embodiments, the second semiconductor device 30 is shown as a single chip. However, the present disclosure is not limited thereto.

The molding layer 80 may be formed on the package substrate 10 so as to cover or surround at least a portion of the first and second semiconductor devices 20 and 30. The molding layer 80 may protect the first and second semiconductor devices 20 and 30 from an outside. The molding layer 80 may include, for example, epoxy molding compound (EMC) or a silicon hybrid material of at least two materials.

FIG. 9 is an example cross-sectional view of a semiconductor package 2000B including one or more of the semiconductor devices 1000A to 1000E according to some embodiments of the present disclosure.

Referring to FIG. 9, the semiconductor package 2000B may include a plurality of semiconductor chips 1020 sequentially stacked on the package substrate 1010. A control chip 1030 may be disposed on the plurality of semiconductor chips 1020. A stack structure of the plurality of semiconductor chips 1020 and the control chip 1030 on the package substrate 1010 may be sealed with an encapsulant 1040 such as a thermosetting resin on the package substrate 1010.

FIG. 9 shows a structure in which six semiconductor chips 1020 are vertically stacked. However, the number and stacking direction of the semiconductor chips 1020 are not limited thereto. The number of semiconductor chips 1020 may be larger or smaller than 6. The plurality of semiconductor chips 1020 may be arranged horizontally and may be disposed on the package substrate 1010 or may be arranged in a combination of vertical and horizontal arrangements. In some other embodiments, the control chip 1030 may be omitted.

The package substrate 1010 may be embodied as a flexible printed circuit board, a rigid printed circuit board rigid printed circuit board, or a combination thereof. The package substrate 1010 may include a substrate internal wiring 1012 and a connection terminal 1014. The connection terminal 1014 may be formed on one surface of the package substrate 1010. A solder ball 1016 may be formed on the other surface of the package substrate 1010. The connection terminal 1014 may be electrically connected to the solder ball 1016 via the substrate internal wiring 1012.

In some other embodiments, the solder ball 1016 may be replaced with a conductive bump or a lead grid array (LGA).

At least one of the plurality of semiconductor chips 1020 and the control chip 1030 may include at least one of the semiconductor devices 1000A to 1000E as described with reference to FIGS. 1 to 7. In particular, the plurality of semiconductor chips 1020 and the control chip 1030 may include via structures 1022 and 1032, respectively. At least one of the via structures 1022 and 1032 may be embodied as the via structure 300 illustrated in FIGS. 1 to 7. In FIG. 9, it is shown that the first impurity area 200, the second impurity area 230, and the gate structure 430 surrounding the via structure 300 are omitted.

The respective via structures 1022 and 1032 of the plurality of semiconductor chips 1020 and the control chip 1030 may be electrically connected to the connection terminal 1014 of the package substrate 1010 via a connection member 1050.

For example, each of the plurality of semiconductor chips 1020 may include a system LSI, a flash memory, DRAM, SRAM, EEPROM, PRAM, MRAM, or RRAM. Furthermore, the control chip 1030 may include a logic circuit, such as a serializer/deserializer (SER/DES) circuit.

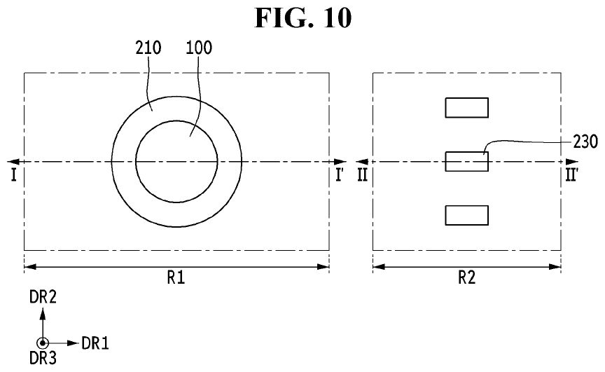

FIGS. 10 to 19 are diagrams of intermediate structures corresponding to intermediate steps of a method for manufacturing a semiconductor device according to some embodiments. For convenience of description, differences thereof from the contents as described above with reference to FIG. 1 to FIG. 9 will be mainly described.

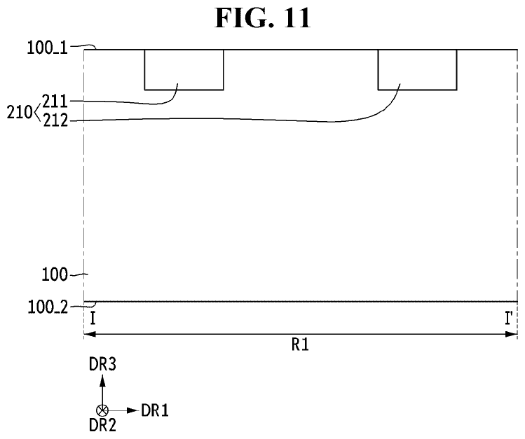

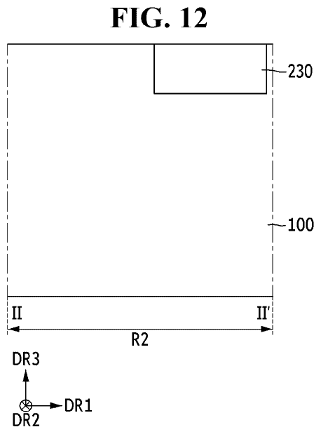

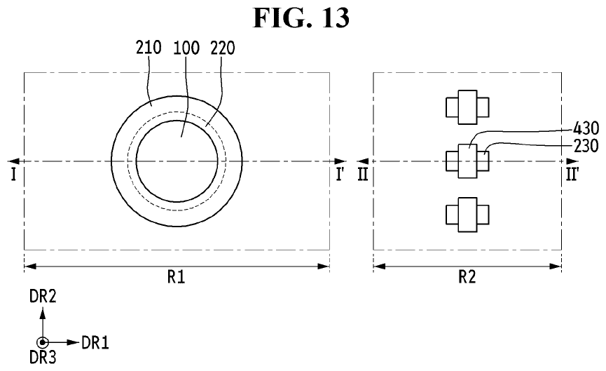

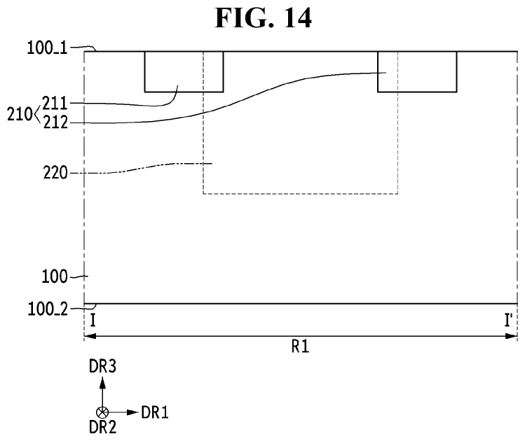

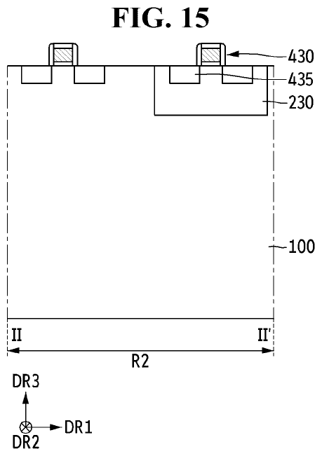

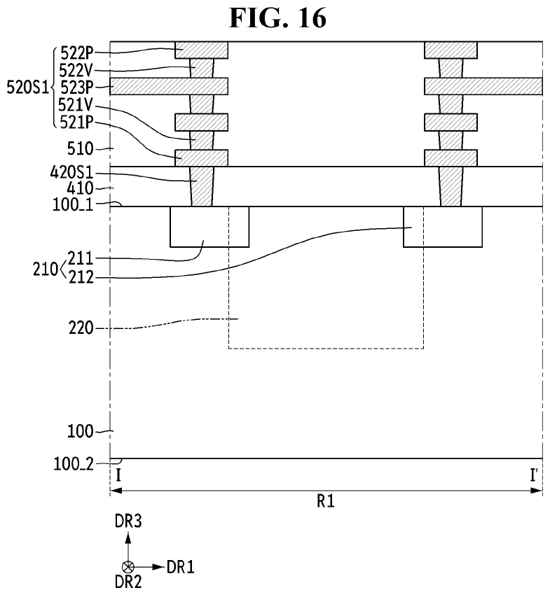

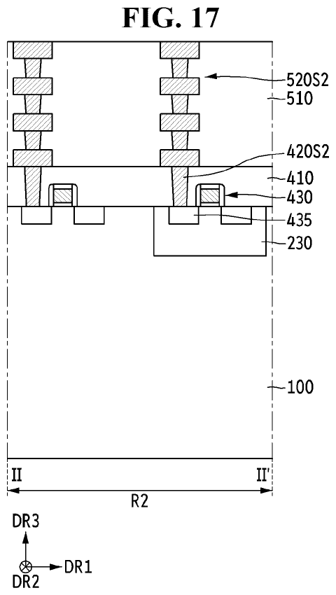

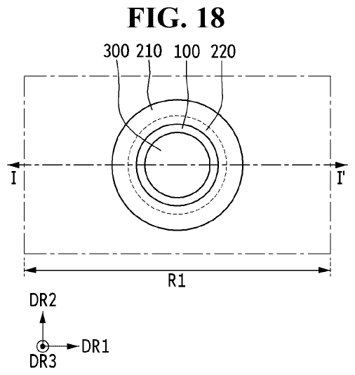

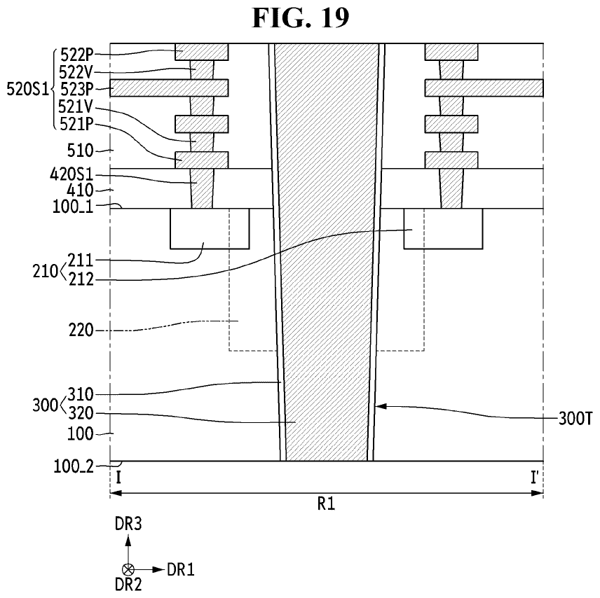

For reference, FIG. 11 and FIG. 12 are cross-sectional views taken along lines I-I′ and II-II′ of FIG. 10, respectively. FIG. 14 and FIG. 15 are cross-sectional views taken along lines I-I′ and II-II′ of FIG. 13, respectively. FIG. 16 and FIG. 17 are diagrams corresponding to cross-sectional views taken along I-I′ and II-II′ in FIG. 13, respectively. FIG. 19 is a diagram corresponding to a cross-sectional view taken along a line I-I′ in FIG. 18.

Referring to FIGS. 10 to 12, the substrate 100 including the first area R1 and the second area R2 may be provided. The first area R1 may be an area where the via hole 300T is later formed, and the second area R2 may be an area where the semiconductor element, for example, the gate structure 430 is formed.

The first impurity area 210 may be formed in the first area R1, and the second impurity area 230 may be formed in the second area R2. The first impurity area 210 and the second impurity area 230 may be formed at the same time. The first impurity area 210 and the second impurity area 230 may be formed to contact the first surface 100_1 of the substrate 100. Referring to FIG. 11, in the cross-sectional view, the first impurity area 210 may include the impurity areas 211 and 212 spaced apart from each other in the first direction DR1.

The first impurity area 210 and the second impurity area 230 may be formed so as to be spaced apart from each other. The first impurity area 210 may be formed to have a circular band shape in the first area R1 as shown in FIG. 10, and a plurality of second impurity areas 230 may be formed in the second area R2. FIG. 10 shows three plural second impurity areas 230. However, the present disclosure is not limited thereto.

Referring to FIGS. 13 to 15, the second impurity area 220 may be formed between the impurity areas 211 and 212, and the gate structure 430 may be formed on the second impurity area 230. The second impurity area 220 may be formed in a circular band shape in the first area R1, as shown in FIG. 13. In the plan view, the first impurity area 210 may be disposed to surround at least a portion of the second impurity area 220.

The gate structure 430 may be formed by sequentially stacking the gate dielectric film (431 in FIG. 3), the gate electrode (432 in FIG. 3), and the capping film (434 in FIG. 3) on the second impurity area 230. The gate dielectric film (431 in FIG. 3) may include an insulating material such as an oxide, and the gate electrode (432 in FIG. 3) may include a conductive material such as metal and/or polysilicon. The spacer (433 in FIG. 3) may be disposed on the sidewall of the gate electrode (432 in FIG. 3).

The source/drain areas 435 may be formed in the second impurity area 230 and may be disposed respectively on both opposing sides of the gate electrode (432 in FIG. 3). The source/drain areas 435 may be formed to be spaced apart from each other and within the second impurity area 230. For example, when the second impurity area 230 is of the N-type conductivity, the source/drain area 435 may be of the P-type conductivity. When the second impurity area 230 is of the P-type conductivity, the source/drain area 435 may be of the N-type conductivity.

Referring to FIG. 16 and FIG. 17, the first interlayer insulating film 410 covering (or overlapping in the third direction DR3) the gate structure 430 may be formed on the first surface 100_1 of the substrate 100. The first interlayer insulating film 410 may be formed on the first and second impurity areas 210 and 220 and the second impurity area 230.

Subsequently, the first contact 420S1 and the second contact 420S2 may be formed in the first interlayer insulating film 410. The first contact 420S1 may be disposed on the first impurity area 210 and connected to the first impurity area 210. The first contact 420S1 may extend into the first interlayer insulating film 410 in the third direction DR3 so as to be connected to the first impurity area 210. The second contact 420S2 may extend into the first interlayer insulating film 410 in the third direction DR3 so as to be electrically connected to the third impurity area 230.

The first contact 420S1 and the second contact 420S2 may be located at the same vertical level in the third direction DR3. The first contact 420S1 and the second contact 420S2 may be formed in the same process.

Subsequently, the second interlayer insulating film 510 may be formed on the first interlayer insulating film 410. The first wiring layer 520S1 and the third wiring layer 520S2 may be formed within the second interlayer insulating film 510. The first wiring layer 520S1 may be disposed on the first contact 420S1 and connected to the first contact 420S1. The first wiring layer 520S1 may constitute a BEOL structure. The third wiring layer 520S2 may be connected to the second contact 420S2 while being disposed on the second contact 420S2.

The first wiring layer 520S1 and the third wiring layer 520S2 may be located at the same vertical level in the third direction DR3. The first wiring layer 520S1 and the third wiring layer 520S2 may be formed in the same process.

Afterwards, referring to FIG. 18 and FIG. 19, the via hole 300T may be formed within the second impurity area 220. The via hole 300T may be spaced apart from the second impurity area 230 and the gate structure 430 in the first direction DR1. The via hole 300T may be formed in the substrate 110 and in the first area R1. The via hole 300T may be surrounded with at least a portion of the first impurity area 210 and the second impurity area 220. The via hole 300T may be formed so as to extend through the first interlayer insulating film 410, the second interlayer insulating film 510, and the substrate 110.

Next, the insulating film 310 may be formed on the inner sidewall of the via hole 300T, and the conductive via 320 filling or on the inside of the via hole 300T may be sequentially formed. The insulating film 310 may be formed conformally along the sidewall of the via hole 300T, and the conductive via 320 may be formed to fill or be in the remaining portion of the via hole 300T.

Subsequently, a planarization process may be performed until an upper surface of the second interlayer insulating film 510 is exposed. The planarization process may be performed, for example, by chemical mechanical polishing (CMP) or a cutting process. Through this planarization process, the via structure 300 as shown in FIG. 19 may be formed.

Next, referring to FIG. 2 and FIG. 3, the third interlayer insulating film 610 may be formed on the second interlayer insulating film 510. The second wiring layer 620S1 and the fourth wiring layer 620S2 may be formed within the third interlayer insulating film 610. The second wiring layer 620S1 may be disposed on the first wiring layer 520S1 and connected to the first contact 420S1 and the first wiring layer 520S1. The second wiring layer 620S1 may be electrically connected to the ground. The fourth wiring layer 620S2 may be disposed on the third wiring layer 520S2 and may be connected to the second contact 420S2 and the third wiring layer 520S2.

The second wiring layer 620S1 and the fourth wiring layer 620S2 may be located at the same vertical level in the third direction DR3. The second wiring layer 620S1 and the fourth wiring layer 620S2 may be formed in the same process.

Accordingly, the semiconductor device 1000A as shown in FIG. 2 and FIG. 3 may be formed.

According to some embodiments, electrical noise that may be generated in the via structure 300 may be reduced by disposing the impurity area 200, the contact 420S1, and the wiring layer 520S1 around (e.g., surrounding at least a portion of) the via structure 300. That is, in some embodiments, the impurity area 200, the contact 420S1, and the wiring layer 520S1 may be electrically connected to the ground such that the impurity area 200, the contact 420S1, and the wiring layer 520S1 and the via structure 300 constitute a metal-insulator-metal (MIM) structure, thereby shielding the noise as described above. Accordingly, a more reliable semiconductor device may be manufactured.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the scope of the present disclosure. Therefore, it should be appreciated that the embodiments as described above are not restrictive but illustrative in all respects.

What is claimed is:

1. A semiconductor device comprising:
a substrate;
a first impurity area in the substrate;
a via structure extending in a first direction into the first impurity area;
a second impurity area that surrounds at least a portion of the via structure;
a first contact that is on the second impurity area and electrically connected to the second impurity area;
a first wiring layer that is on the first contact and electrically connected to the first contact; and
a second wiring layer that is on the first wiring layer and electrically connected to a ground.

2. The semiconductor device of claim 1, wherein in a plan view, the first impurity area and the second impurity area surround at least a portion of a sidewall of the via structure.

3. The semiconductor device of claim 1, wherein at least a portion of the first impurity area overlaps at least a portion of the second impurity area in the first direction.

4. The semiconductor device of claim 1, wherein in a plan view, the first contact and the first wiring layer surround at least a portion of a sidewall of the via structure.

5. The semiconductor device of claim 1, wherein the second wiring layer and the first wiring layer are free from overlap in the first direction.

6. The semiconductor device of claim 5, wherein a distance between the second wiring layer and a sidewall of the via structure in a second direction that is perpendicular to the first direction is different from a distance between the first wiring layer and the sidewall of the via structure in the second direction.

7. The semiconductor device of claim 1, wherein the second wiring layer overlaps at least a portion of the first wiring layer in the first direction.

8. The semiconductor device of claim 7, wherein a distance between the second wiring layer and a sidewall of the via structure in a second direction that is perpendicular to the first direction is equal to a distance between the first wiring layer and the sidewall of the via structure in the second direction.

9. The semiconductor device of claim 1, further comprising:
a third impurity area in the substrate;
a gate structure on the substrate;
a second contact that is on the substrate and electrically connected to the third impurity area; and
a third wiring layer that is on the second contact and electrically connected to the second contact,
wherein a distance between an upper surface of the first contact and an upper surface of the substrate in the first direction is equal to a distance between an upper surface of the second contact and the upper surface of the substrate in the first direction.

10. The semiconductor device of claim 1, wherein the via structure comprises a via hole that extends in the first direction into the substrate, an insulating film that is on an inner sidewall of the via hole, and a conductive via in the via hole.

11. The semiconductor device of claim 1, wherein the first impurity area and the second impurity area comprise materials of a same conductivity type.

12. A semiconductor device comprising:
a substrate that comprises a first surface extending in a first direction and a second direction that intersect each other;
an impurity area that is in the substrate and comprises a first area and a second area;
a via structure comprising:
a via hole that extends into the first area in a third direction that is perpendicular to the first direction and the second direction; and
a conductive via in the via hole;
a first contact on the second area;
a first wiring layer electrically connected to the impurity area; and
a second wiring layer electrically connected to a ground,
wherein in a plan view, the impurity area, the first contact, and the first wiring layer surround at least a portion of a sidewall of the via structure.

13. The semiconductor device of claim 12, wherein in the plan view, the second area surrounds at least a portion of the first area.

14. The semiconductor device of claim 12, wherein a depth in the third direction of the first area from the first surface of the substrate is greater than a depth in the third direction of the second area from the first surface of the substrate.

15. The semiconductor device of claim 12, wherein the first area is between the second area and the via structure.

16. The semiconductor device of claim 12, wherein at least a portion of the first area and the sidewall of the via structure are in contact with each other.

17. A semiconductor device comprising:
a substrate comprising a first area and a second area;
a via structure that extends in a first direction into the first area of the substrate;
a first impurity area that is in the first area of the substrate and contacts the via structure;
a first wiring structure electrically connected to the first impurity area, wherein the first wiring structure comprises:
a first contact on the first area of the substrate; and
a first wiring layer that is on the first contact and electrically connected to the first contact;
a second impurity area in the second area of the substrate;
a gate structure on the second area of the substrate; and
a second wiring structure electrically connected to the second impurity area, wherein the second wiring structure comprises:
a second contact on the second area of the substrate; and
a second wiring layer that is on the second contact and electrically connected to the second contact,
wherein a distance between an upper surface of the first contact and an upper surface of the substrate in the first direction is equal to a distance between an upper surface of the second contact and the upper surface of the substrate in the first direction.

18. The semiconductor device of claim 17, wherein a distance between an upper surface of the first wiring layer and the upper surface of the substrate in the first direction is equal to a distance between an upper surface of the second wiring layer and the upper surface of the substrate in the first direction.

19. The semiconductor device of claim 17, wherein in a plan view, the first impurity area and the first wiring structure surround at least a portion of a sidewall of the via structure.

20. The semiconductor device of claim 17, wherein:
the first wiring structure further comprises a third wiring layer that is on the first wiring layer and electrically connected to a ground,
the second wiring structure further comprises a fourth wiring layer on the second wiring layer,
a distance between an upper surface of the third wiring layer and the upper surface of the substrate in the first direction is equal to a distance between an upper surface of the fourth wiring layer and the upper surface of the substrate in the first direction.
